(19) United States
(12) Patent Application Publication
(10) Pub. No.: US 2009/0017388 A1
(43) Pub. Date: Jan. 15, 2009

(54) SUBSTRATE STRUCTURE FOR COLOR FILTER AND COLOR FILTER HAVING THE SAME

(75) Inventors: Sang-kwon Wee, Yongin-si (KR); Sang-joon Lee, Yongin-si (KR)

Correspondence Address: STANZIONE & KIM, LLP, 919 18TH STREET, N.W., SUITE 440, WASHINGTON, DC, 20006, US

(73) Assignee: Samsung Electronics Co., Ltd., Suwon-si (KR)

(21) Appl. No.: 11/872,073

(22) Filed: Oct. 15, 2007

(30) Foreign Application Priority Data
Jul. 9, 2007 (KR) 2007-68820

(51) Int. Cl. G03F 1/00

(52) U.S. Cl. 430/7

(57) ABSTRACT

Provided is a substrate structure for a color filter and a color filter having the same. The substrate structure for color filter includes: a transparent substrate on which a plurality of pixels are defined by a black matrix; and an ink-philic pattern which is formed in a predetermined pattern on a surface of the substrate.

### CROSS-REFERENCE TO RELATED APPLICATIONS

This application claims the benefit of Korean Patent Application No. 10-2007-0068820, filed on Jul. 9, 2007, in the Korean Intellectual Property Office, the disclosure of which is incorporated herein in its entirety by reference.

### BACKGROUND OF THE INVENTION

1. Field of the Invention

The present invention relates to a color filter, and more particularly, to a substrate structure for color filter that can be used to form an ink layer having a uniform thickness and a color filter having the substrate structure for color filter.

2. Description of the Related Art

Conventionally, cathode ray tubes (CRTs) have been generally used to display image information in televisions and computers. However, flat panel displays such as liquid crystal displays (LCDs), plasma display panel (PDPs), organic light emitting diode (OLEDs), light emitting diode (LED) displays, or field emission displays (FEDs) are now being used due to their large screen size. Of the flat panel displays, LCDs, which are mainly used in computer monitors or notebook computers, have drawn much attention due to their low power consumption.

An LCD includes a color filter that forms a desired color image by transmitting white light modulated by a liquid crystal layer. The color filter has a structure in which a plurality of red R, green G, and blue B pixels are arranged in a predetermined pattern on a transparent substrate. The pixels are defined by a black matrix. To manufacture the color filter, a dyeing method, a pigment dispersion method, a printing method, or an electro-deposition method has been conventionally used. However, these methods have low process efficiencies and high manufacturing costs since predetermined processes for each color must be performed repeatedly. Thus, recently, an inkjet method which can reduce manufacturing costs and which is simple has been proposed. In the method of manufacturing a color filter using the inkjet method, the color filter is manufactured by ejecting ink droplets of a predetermined color, for example, red R, green G, and blue B color, into pixels by using an inkjet head.

When the color filter is manufactured using the inkjet method, the black matrix is formed of an ink-phobic organic material to prevent ink of different colors from overflowing between adjacent pixels. The black matrix is formed by patterning a light shielding layer formed of the ink-phobic organic material after the light shielding layer is formed on a substrate. However, after the black matrix is formed, the ink-phobic organic material can remain on a surface of the substrate at edges of the pixels where the black matrix and the substrate intersect. If the ink-phobic organic material remains on the surface of the substrate at the edges of the pixels, ink droplets ejected from the inkjet head are filled in only a center portion of the pixel as shown FIG. 1, and may not be filled to the edge of the pixel. Thus, if the color filter is manufactured in a state in which the ink is not filled to the edge of the pixel, leakage of light occurs at the edge of the pixel. Such leakage of light causes panels of poor quality to be produced as a corresponding liquid crystal display will have a reduced color reproduction range.

### SUMMARY OF THE INVENTION

The present invention provides a substrate structure for a color filter which can be used to form ink layers having a uniform thickness to edge portions of a pixel and a color filter having the substrate structure for a color filter.

According to an aspect of the present invention, there is provided a substrate structure for color filter, including: a transparent substrate on which a plurality of pixels are defined by a black matrix; and an ink-philic pattern which is formed in a predetermined pattern on a surface of the substrate.

The ink-philic pattern may have a plurality of strips which extend from a center portion to edge portions of the pixel. In this case, the ink-philic pattern may include corner portions.

The ink-philic pattern may have a plurality of strips, wherein ends of at least some of the strips are connected to the corner portions of the pixel.

According to another aspect of the present invention, there is provided a color filter, including: a transparent substrate: an ink-philic pattern formed in a predetermined pattern on a surface of the substrate: and a black matrix that is formed on the substrate in which the ink-philic pattern is formed and defines a plurality of pixels.

The ink-philic pattern may have a plurality of strips which extends from a center portion to edge portions of the pixel or a plurality of strips, wherein ends of at least some of the strips are connected to the corner portions of the pixel.

The color filter may further include an ink layer of a predetermined color formed in the pixel. In this case, the ink layer may be formed using an inkjet method.

The substrate may be made of a glass substrate, and the black matrix may be made of an ink-phobic material.

### BRIEF DESCRIPTION OF THE DRAWINGS

The above and other features and advantages of the present invention will become more apparent by describing in detail exemplary embodiments thereof with reference to the attached drawings in which:

FIG. 1 shows a conventional color filter in which ink is not filled to an edge of a pixel;

FIG. 2 is a plan view showing a part of a color filter according to an embodiment of the present invention;

FIG. 3 is a perspective view showing the color filter of FIG. 2; and

FIGS. 4 through 8 are plan views showing modified examples of a color filter according to an embodiment of the present invention.

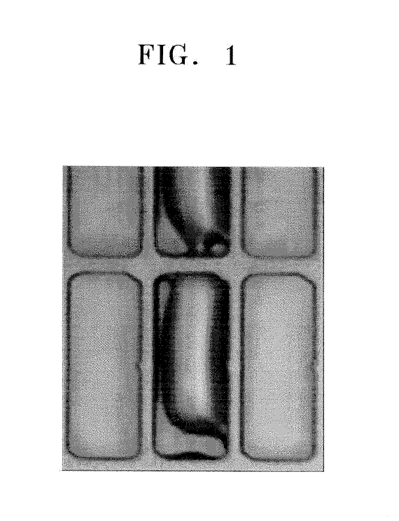

### DETAILED DESCRIPTION OF THE PREFERRED EMBODIMENTS

The present invention will now be described more fully with reference to the accompanying drawings in which exemplary embodiments of the invention are shown. In the drawings, the thicknesses of layers and regions are exaggerated for clarity, and like reference numerals refer to like elements.

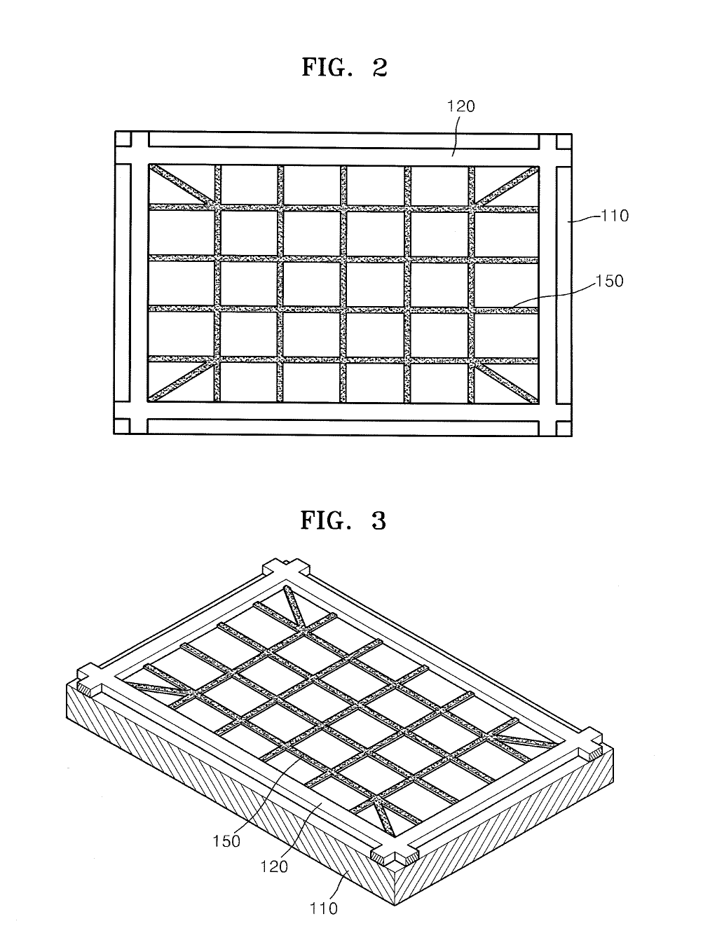

FIG. 2 is a plan view showing a part of a color filter according to an embodiment of the present invention. FIG. 3 is a perspective view showing the color filter of FIG. 2.

Referring to FIGS. 2 and 3, the color filter according to an embodiment of the present invention includes a substrate structure and a black matrix 120 formed on the substrate structure. Here, a plurality of pixels are defined by the black matrix 120 on the substrate structure. Ink layers of predetermined color are formed in the pixels. The ink layers can be formed using an inkjet method. More particularly, ink droplets of predetermined color are ejected from an inkjet head into the pixels, and the ejected ink droplets are filled in the pixels, and thus the ink layers are formed.

The substrate structure includes a transparent substrate 110 and an ink-philic pattern 150 which is formed in a predetermined pattern on a surface of the substrate 110. The substrate 110 can generally be made of a glass substrate, but it is not limited thereto. The ink-philic pattern 150 allows ink ejected from the inkjet head (not shown) to be entirely and uniformly filled in the pixels defined by the black matrix 120. For this, the ink-philic pattern 150 may be formed to have a plurality of strips which extend from a center portion to edge portions of the pixel as shown FIGS. 2 and 3. Here, the edge portions of the pixel may include corner portions. Thus, if the ink-philic pattern 150 having a plurality of strips extended from the center portion of the pixel to the edge portions is formed on the surface of the substrate 110, when the ink ejected from the inkjet head in the following processes is filled in the pixel, the ink dropped onto the center portion of the pixel is spread along the ink-philic pattern 150 to the edge portions, in particular, to the corner portions. The ink-philic pattern 150 can be formed by applying a predetermined ink-philic material on the surface of the substrate 110, and then by patterning the ink-philic material in a predetermined pattern by using a photolithography process. Here, the ink-philic material has an affinity with respect to the ink filled in the pixel and is the opposite of an ink-phobic material.

The black matrix 120 is formed on the substrate 110 where the aforementioned ink-philic pattern 150 is formed to define a plurality of pixels. The black matrix 120 can be formed by applying a predetermined ink-phobic material on the substrate 110 where the ink-philic pattern 150 is formed, and then by patterning the ink-phobic material in a predetermined pattern by a photolithography process. Although it is not shown in the drawing, if ink layers of predetermined color are formed in the pixels defined by the black matrix 120, a color filter according to an embodiment of the present invention is formed. Here, as described above, the ink layers can be formed by ejecting ink droplets from the inkjet head into the pixels. In this case, the ink dropped onto each pixel is moved along the ink-philic pattern 150 and is entirely and uniformly spread in the pixels. Thus, ink layers having a uniform thickness can be formed in the pixels.

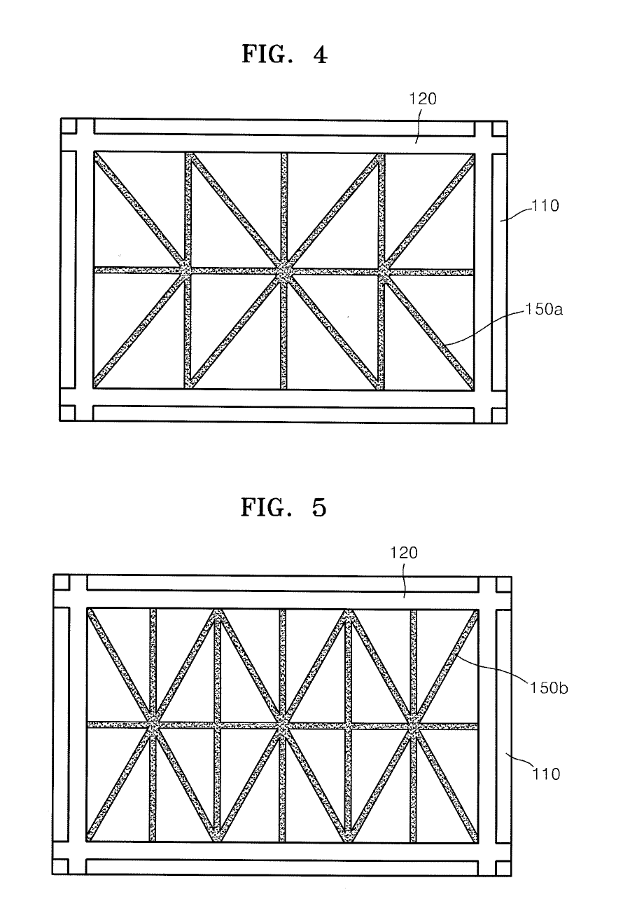

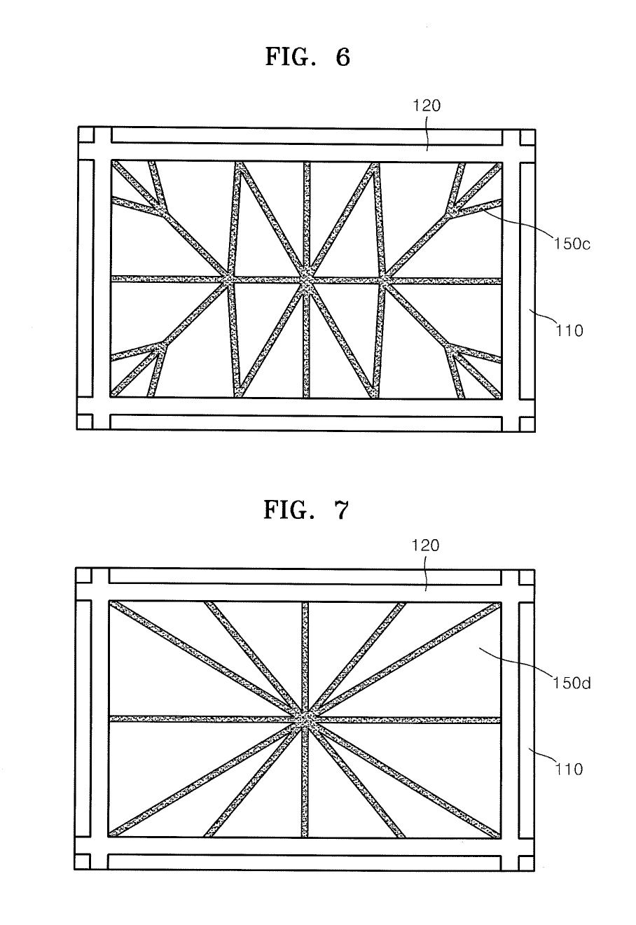

FIGS. 2 and 3 show examples of the ink-philic pattern 150 that can be formed on the surface of the substrate 110, but the present invention is not limited thereto, and the shape of the ink-philic pattern can be varied. FIGS. 4 through 8 are plan views showing modified examples of a color filter, in which ink-philic patterns 150a, 150b, 150c, 150d, 150e having different shapes from that of the ink-philic pattern of FIG. 2 are formed, according to embodiments of the present invention.

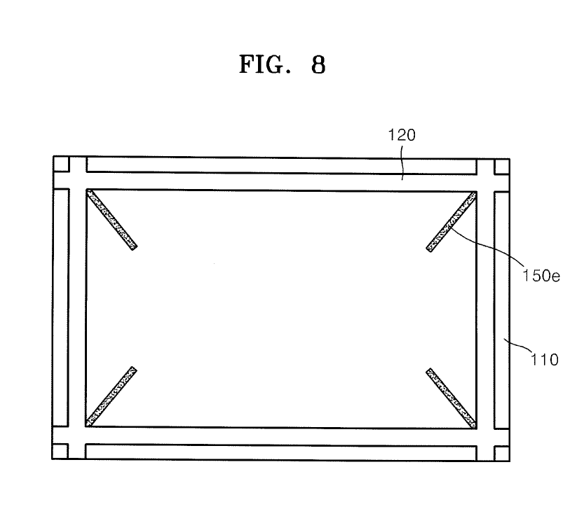

First, referring to FIGS. 4 through 7, the ink-philic patterns 150a, 150b, 150c, 150d have a plurality of strips which extends from a center portion to edge portions of a pixel, in particular, to corner portions of the pixel. Ink ejected from an inkjet head into the pixel can be entirely and uniformly spread in the pixel by the ink-philic patterns 150a, 150b, 150c, 150d. Referring to FIG. 8, unlike the above description, the ink-philic pattern 150e may have a plurality of strips, wherein ends of at least some of the strips are connected to the corner portions of the pixel. In this case, the ink ejected from the inkjet head into the pixels is moved along the ink-philic pattern 150e and is filled to the corner portions of the pixel, and thus, ink layers having an entirely uniform thickness can be formed in the pixel. The shape of the ink-philic pattern described above is only an example, the present invention is not limited thereto, and the shape of the ink-philic pattern can be varied.

A color filter for a liquid crystal display has been explained above, but the present invention is not limited thereto, and can be applied to a field in which a functional material layer having a uniform thickness is applied using an inkjet method. For example, a substrate described above, on which the ink-philic pattern is formed, can be used in a case in which an organic light emitting layer is formed using the inkjet method when manufacturing organic light emitting diodes (OLED) or in a case in which a semiconductor material is formed using the inkjet method when manufacturing organic thin film transistors (OTFT).

As describe above, according to the present invention, by forming an ink-philic pattern having a plurality of strips connected from a center portion to edge portions of a pixel on a surface of a substrate, ink which is ejected from an inkjet head and is dropped onto the pixel can be entirely and uniformly filled in the pixel. Accordingly, since ink layers having a uniform thickness can be formed in the pixels, leakage of light through the pixel, which has been a conventional problem, can be prevented. As a result, a color reproduction range of the pixels can be improved, so that poor quality panels of liquid crystal displays can be prevented from being produced.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. A substrate structure for color filter, comprising:
a transparent substrate on which a plurality of pixels are defined by a black matrix; and
an ink-philic pattern which is formed in a predetermined pattern on a surface of the substrate.

2. The substrate structure for color filter of claim 1, wherein the ink-philic pattern has a plurality of strips which extend from a center portion to edge portions of the pixel.

3. The substrate structure for color filter of claim 2, wherein the ink-philic pattern further comprises corner portions.

4. The substrate structure for color filter of claim 1, wherein the ink-philic pattern has a plurality of strips, wherein ends of at least some of the strips are connected to the corner portions of the pixel.

5. The substrate structure for color filter of claim 1, wherein the substrate is made of a glass substrate.

6. A color filter, comprising:
a transparent substrate:
an ink-philic pattern formed in a predetermined pattern on a surface of the substrate: and
a black matrix that is formed on the substrate in which the ink-philic pattern is formed and defines a plurality of pixels.

7. The color filter of claim 6, wherein the ink-philic pattern has a plurality of strips which extend from a center portion to edge portions of the pixel.

8. The color filter of claim 7, wherein the ink-philic pattern further comprises corner portions.

9. The color filter of claim 6, wherein the ink-philic pattern has a plurality of strips, wherein ends of at least some of the strips are connected to the corner portions of the pixel.

10. The color filter of claim 6, further comprising an ink layer of a predetermined color formed in the pixel.

11. The color filter of claim 10, wherein the ink layer is formed using an inkjet method.

12. The color filter of claim 6, wherein the substrate is made of a glass substrate.

13. The color filter of claim 6, wherein the black matrix is made of an ink-phobic material.
